(19) United States
(12) Patent Application Publication
(10) Pub. No.: US 2024/0069062 A1
(43) Pub. Date: Feb. 29, 2024

(54) ACCELEROMETER

(71) Applicant: AAC Kaitai Technologies (Wuhan) CO., LTD, Wuhan (CN)

(72) Inventors: Shitao Yan, Shenzhen (CN); Shan Yang, Shenzhen (CN); Zhan Zhan, Shenzhen (CN); Zhao Ma, Shenzhen (CN); Xiao Kan, Shenzhen (CN); Hongtao Peng, Shenzhen (CN); Yang Li, Shenzhen (CN); Kahkeen Lai, Singapore (SG); Veronica Tan, Singapore (SG)

(21) Appl. No.: 18/088,823

(22) Filed: Dec. 27, 2022

Related U.S. Application Data
(63) Continuation of application No. PCT/CN2022/122711, filed on Sep. 29, 2022.

(30) Foreign Application Priority Data
Aug. 31, 2022 (CN) 202211055760.3

(51) Int. Cl. G01P 15/125; G01P 15/18

(52) U.S. Cl. CPC G01P 15/125; G01P 15/18; G01P 2015/0831

(57) ABSTRACT

The present invention provides an accelerometer, including base, anchor points, seesaw structures elastically, and a differential detection assembly; the seesaw structures includes a first seesaw structure and a second seesaw structure which are parallel to each other and placed in reverse; the anchor points includes a first anchor point and a second anchor point; the first seesaw structure includes a first elastic member and a first mass block connected to the first elastic member; the first mass block is driven by a normal phase carrier drive signal from the first anchor point; the second seesaw structure includes a second elastic member and a second mass block connected to the second elastic member; and the second mass block is driven by a reversed phase carrier drive signal from the second anchor point. The accelerometer can effectively suppress the impact of noise of an angular acceleration of rotation.

### CROSS-REFERENCE TO RELATED APPLICATIONS

The application is a continuation of International Application No. PCT/CN2022/122711 filed on Sep. 29, 2022, which is incorporated herein by reference in its entireties.

### TECHNICAL FIELD

The present invention relates to the technical field of micro electro mechanical systems, in particular to an accelerometer.

### BACKGROUND

For multi-axis accelerometers in the related technology, Z-axis out-of-plane acceleration detection and Y-axis in-plane acceleration detection share an asymmetric rotational test mass. X-axis in-plane acceleration detection takes an entire seesaw structure as a linear test mass. Three-axis detection is achieved through corresponding capacitance plates.

However, acceleration detection modalities of the Y axis and the Z axis are the same as motion modalities under the action of external angular acceleration around the Z axis and the Y axis, and the center of mass of a structure is not at the same point as the center of mass of the test mass, so that the accelerometer has a low ability to resist the impact of the external angular acceleration around the Z axis and the Y axis during the detection of the Y axis and the Z axis. At the same time, when a base tilts and deforms around the Y axis due to thermal stress and the like, a differential detection capacitor for Z-axis detection will be directly affected by the tilting of the base, resulting in a bias error in an output due to the tilting of the base.

### SUMMARY

The present invention aims to provide an accelerometer to suppress the impact of an angular acceleration of rotation in the relevant technology on detection.

An embodiment of the present invention provides an accelerometer, including base, anchor points arranged on the base, and seesaw structures elastically connected to the anchor points, the accelerometer further includes a differential detection assembly used for detecting accelerations of the seesaw structures; the seesaw structures include a first seesaw structure and a second seesaw structure which are parallel to each other and placed in reverse; the anchor points include a first anchor point elastically connected to the first seesaw structure, and a second anchor point elastically connected to the second seesaw structure;
the first seesaw structure includes a first elastic member connected to the first anchor point, and a first mass block connected to the first elastic member; the first mass block is driven by a normal phase carrier drive signal from the first anchor point;
the second seesaw structure includes a second elastic member connected to the corresponding second anchor point, and a second mass block connected to the second elastic member; and the second mass block is driven by a reversed phase carrier drive signal from the second anchor point.

Further, the first mass block and the second mass block are asymmetric structures;
the first mass block includes a first mass portion connected to the first elastic member, and a second mass portion connected to the first mass portion;
the second mass block includes a third mass portion connected to the second elastic member, and a fourth mass portion connected to the third mass portion;
the moment of inertia of the first mass portion around the first elastic member matches the moment of inertia of the fourth mass portion around the second elastic member; and the moment of inertia of the second mass portion around the first elastic member matches the moment of inertia of the third mass portion around the second elastic member.

Further, the differential detection assembly includes a first Z-axis capacitance detection electrode arranged on the base; the first Z-axis capacitance detection electrode directly faces one side of the first mass block close to the first elastic member and one side of the second mass block facing away from the second elastic member, so as to form a first Z-axis differential detection capacitor and a second Z-axis differential detection capacitor, wherein
a product of an area of a plate of the first Z-axis differential detection capacitor and a distance between the plate and the first elastic member is equal to a product of an area of a plate of the second Z-axis differential detection capacitor and a distance between the plate and the second elastic member, and plate spacings of the first Z-axis differential detection capacitor and the second Z-axis differential detection capacitor are the same.

Further, the differential detection assembly further includes a second Z-axis capacitance detection electrode arranged on the base; the second Z-axis capacitance detection electrode directly faces one side of the first mass block facing away from the first elastic member and one side of the second mass block close to the second elastic member, so as to form a third Z-axis differential detection capacitor and a fourth Z-axis differential detection capacitor, wherein
a product of an area of a plate of the third Z-axis differential detection capacitor and a distance between the plate and the first elastic member is equal to a product of an area of a plate of the fourth Z-axis differential detection capacitor and a distance between the plate and the second elastic member, and plate spacings of the third Z-axis differential detection capacitor and the fourth Z-axis differential detection capacitor are the same;
a product of the area of the plate of the third Z-axis differential detection capacitor and the distance between the plate and the first elastic member is equal to a product of the area of the plate of the first Z-axis differential detection capacitor and the distance between the plate and the first elastic member, and plate spacings of the third Z-axis differential detection capacitor and the first Z-axis differential detection capacitor are the same, so as to form a dual-differential Z-axis detection capacitor.

Further, the first mass block further includes a first side wall perpendicular to the Y axis; the second mass block further includes a second side wall perpendicular to the Y axis; the differential detection assembly includes a first Y-axis capacitance detection electrode arranged on the base; the first Y-axis capacitance detection electrode directly faces the first side wall and the second side wall to form a first Y-axis differential detection capacitor and a second Y-axis differential detection capacitor, wherein
plate spacings of the first Y-axis differential detection capacitor and the second Y-axis differential detection capacitor are the same.

Further, the first mass block further includes a third side wall opposite to the first side wall; the second mass block further includes a fourth side wall opposite to the second side wall; the differential detection assembly further includes a second Y-axis capacitance detection electrode arranged on the base; the second Y-axis capacitance detection electrode directly faces the third side wall and the fourth side wall to form a third Y-axis differential detection capacitor and a fourth Y-axis differential detection capacitor, wherein
plate spacings of the third Y-axis differential detection capacitor and the fourth Y-axis differential detection capacitor are the same; the third Y-axis differential detection capacitor and the first Y-axis differential detection capacitor have the same overlapping areas and the same plate spacings, and the fourth Y-axis differential detection capacitor and the second Y-axis differential detection capacitor have the same overlapping areas and the same plate spacings, so as to form a dual-differential Y-axis detection capacitor.

Further, the first mass block further includes a fifth side wall perpendicular to the X axis; the second mass block further includes a sixth side wall perpendicular to the X axis; the differential detection assembly includes a first X-axis capacitance detection electrode arranged on the base; the first X-axis capacitance detection electrode directly faces the fifth side wall and the sixth side wall to form a first X-axis differential detection capacitor and a second X-axis differential detection capacitor, wherein
plate spacings of the first X-axis differential detection capacitor and the second X-axis differential detection capacitor are the same.

Further, the first mass block further includes a seventh side wall opposite to the fifth side wall; the second mass block further includes an eighth side wall opposite to the sixth side wall; the differential detection assembly further includes a second X-axis capacitance detection electrode arranged on the base; the second X-axis capacitance detection electrode directly faces the seventh side wall and the eighth side wall to form a third X-axis differential detection capacitor and a fourth X-axis differential detection capacitor, wherein
plate spacings of the third X-axis differential detection capacitor and the fourth X-axis differential detection capacitor are the same; the third X-axis differential detection capacitor and the first X-axis differential detection capacitor have the same overlapping areas and the same plate spacings, and the fourth X-axis differential detection capacitor and the second X-axis differential detection capacitor have the same overlapping areas and the same plate spacings, so as to form a dual-differential X-axis detection capacitor.

Further, at least two first anchor points are provided, which are oppositely arranged on the base; at least two first elastic members are provided; one end of each first elastic member is connected with the first mass block, and the other end is connected with the corresponding first anchor point;
at least two second anchor points are provided, which are oppositely arranged on the base;
at least two second elastic members are provided; and one end of each second elastic member is connected with the second mass block, and the other end is connected with the corresponding second anchor point.

Further including an upper cover arranged on one side of the seesaw structure facing away from the base.

Further, the first seesaw structure and the second seesaw structure are nested.

The beneficial effects of the present invention lie in: the normal phase carrier drive signal and the reversed phase carrier drive signal with opposite phases are respectively applied to the first anchor point and the second anchor point of the parallel and reversed first seesaw structure and second seesaw structure. Potentials of the first seesaw structure and the second seesaw structure are unified with potentials at the first anchor point and the second anchor point, respectively, to form differential drive. By a detection method in which two parallel and reversed seesaw structures are driven by two carrier differential drives, when the base tilts around rotation axes where the first elastic member and the second elastic member are located under stress or other external factors, caused common mode changes of the differential detection assembly are canceled out, which can effectively suppress the impact of noise of an angular acceleration of rotation.

### BRIEF DESCRIPTION OF THE DRAWINGS

FIG. 1 is a schematic three-dimensional diagram of anchor points and seesaw structures provided according to an embodiment of the present invention;

FIG. 2 is a schematic planar diagram of anchor points and seesaw structures provided according to an embodiment of the present invention;

FIG. 3 is a modality of a first seesaw structure in an X-axis acceleration detection modality provided according to an embodiment of the present invention;

FIG. 4 is a modality of a second seesaw structure in an X-axis acceleration detection modality provided according to an embodiment of the present invention;

FIG. 5 is a modality of a first seesaw structure in a Y-axis acceleration detection modality provided according to an embodiment of the present invention;

FIG. 6 is a modality of a second seesaw structure in a Y-axis acceleration detection modality provided according to an embodiment of the present invention;

FIG. 7 is a modality of a first seesaw structure in a Z-axis acceleration detection modality provided according to an embodiment of the present invention; and

FIG. 8 is a modality of a second seesaw structure in a Z-axis acceleration detection modality provided according to an embodiment of the present invention.

### DETAILED DESCRIPTION OF THE EMBODIMENTS

The present invention is further described below in combination with accompanying drawings and implementations.

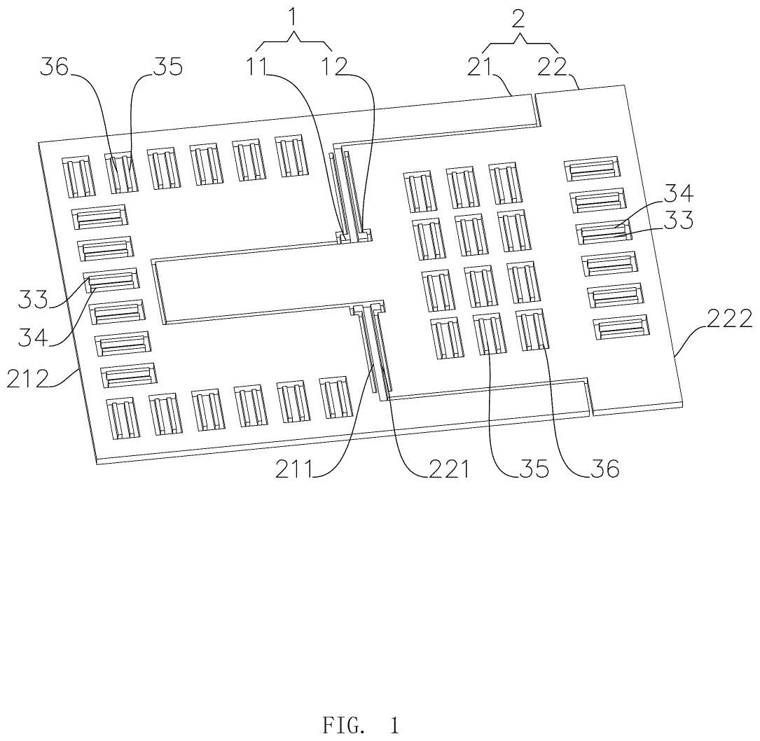

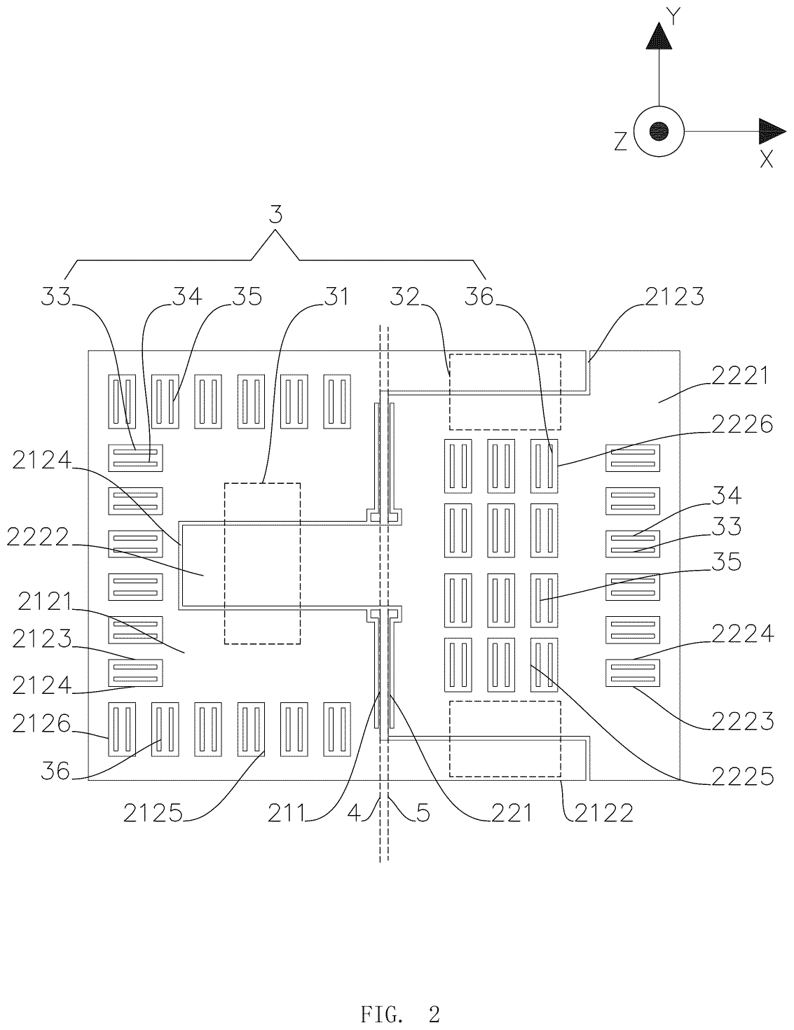

Referring to FIG. 1 and FIG. 2, an embodiment of the present invention provides an accelerometer, which includes a base, anchor points 1 arranged on the base, and seesaw structures 2 elastically connected to the anchor points 1. The accelerometer further includes a differential detection assembly 3 for detecting an acceleration of the seesaw structures 2. The seesaw structures 2 include a first seesaw structure 21 and a second seesaw structure 22 which are parallel to each other and placed in reverse. The anchor points 1 include a first anchor point 11 elastically connected to the first seesaw structure 21, and a second anchor point 12 elastically connected to the second seesaw structure 22. The first seesaw structure 21 includes a first elastic member 211 connected to the first anchor point 11, and a first mass block 212 connected to the first elastic member 211. The first mass block 212 is driven by a normal phase carrier drive signal from the first anchor point 11. The second seesaw structure 22 includes a second elastic member 221 connected to the corresponding second anchor point 12, and a second mass block 222 connected to the second elastic member 221. The second mass block 222 is driven by a reversed phase carrier drive signal from the second anchor point 12.

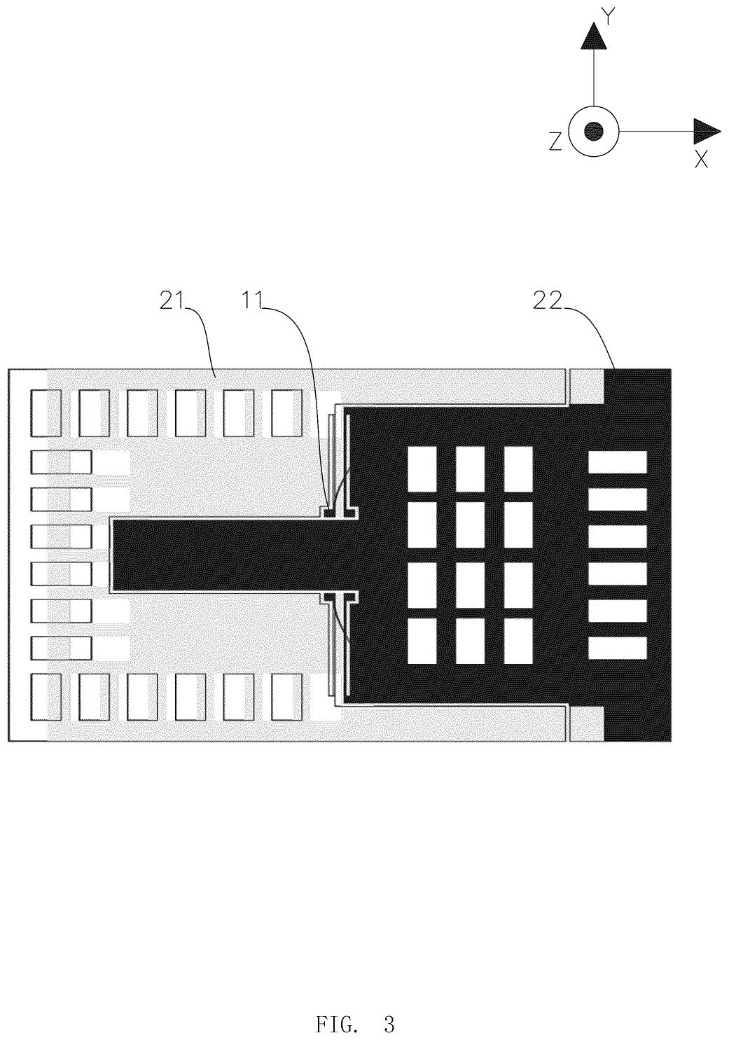

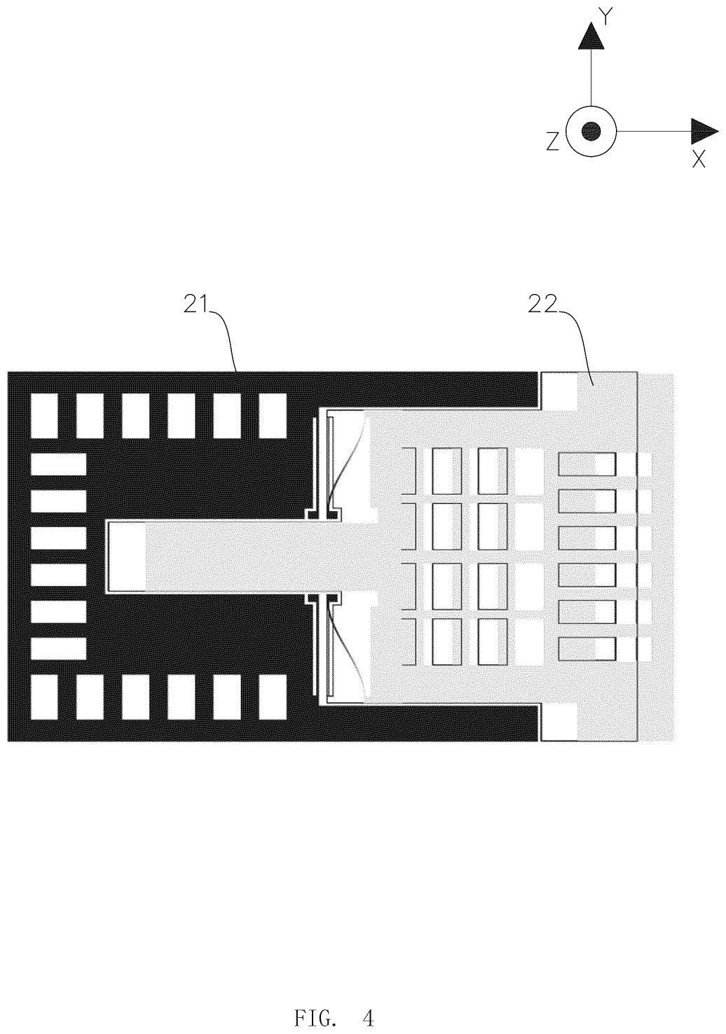

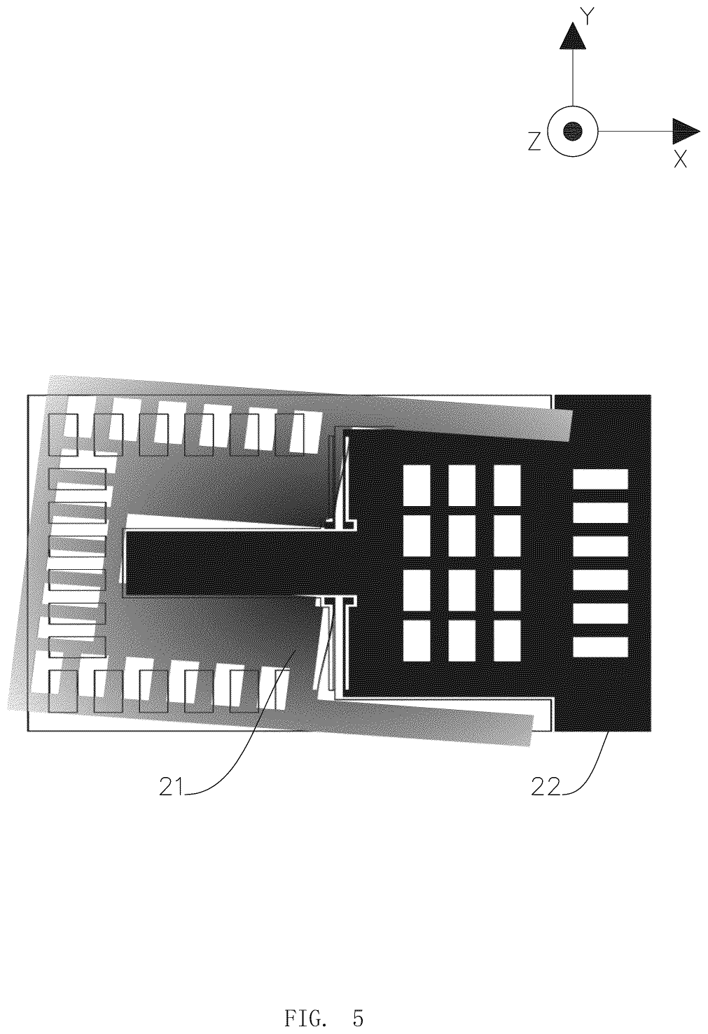

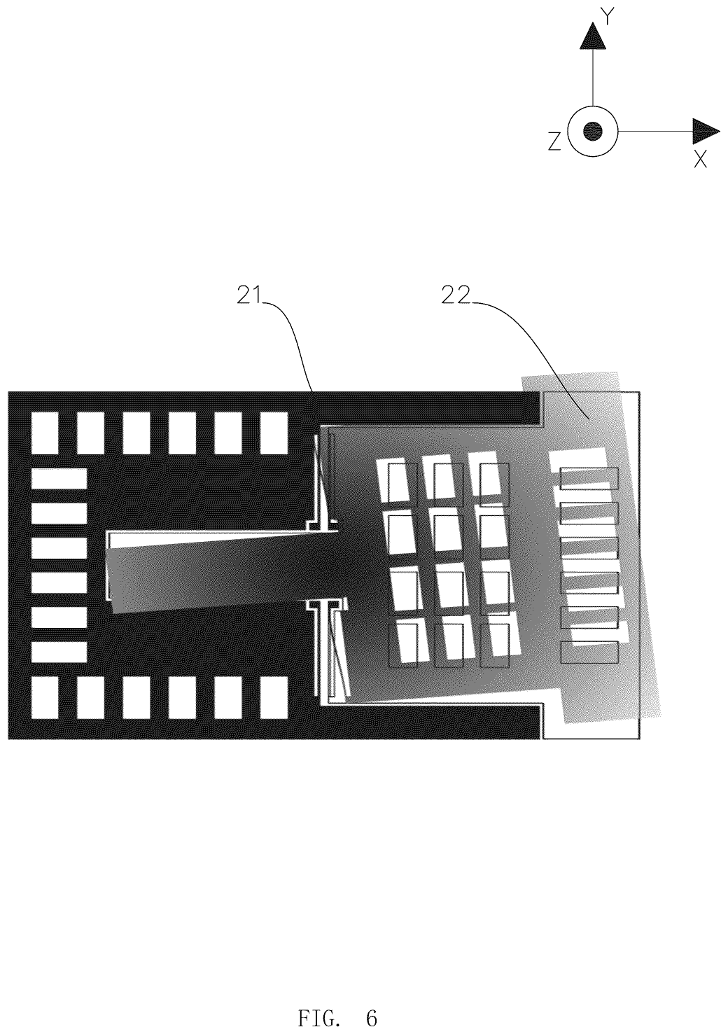

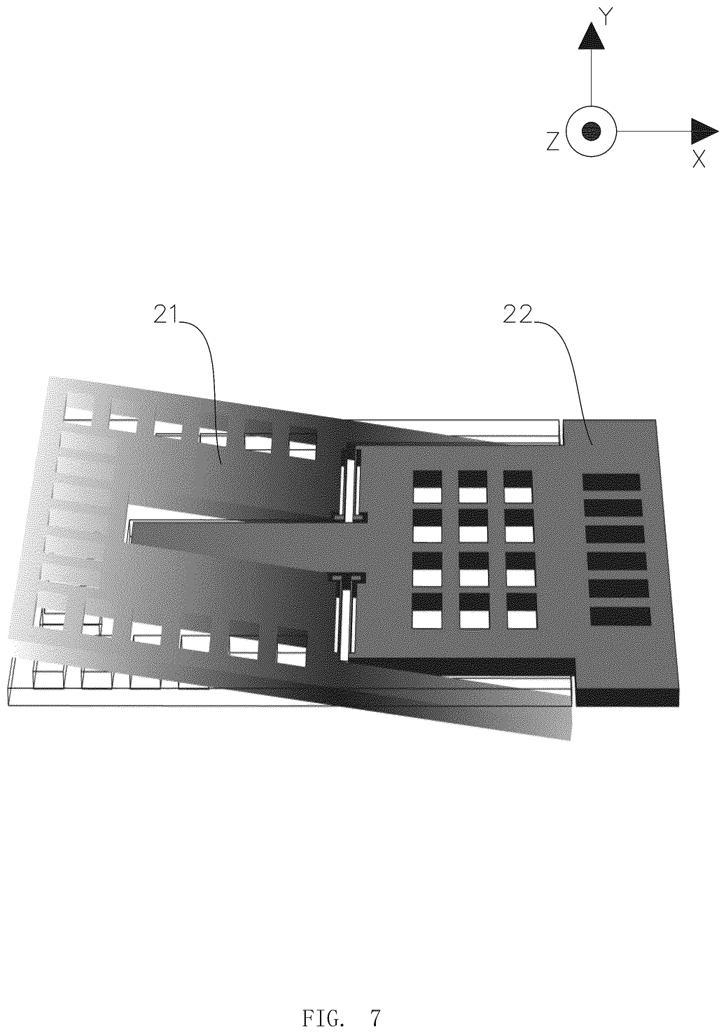

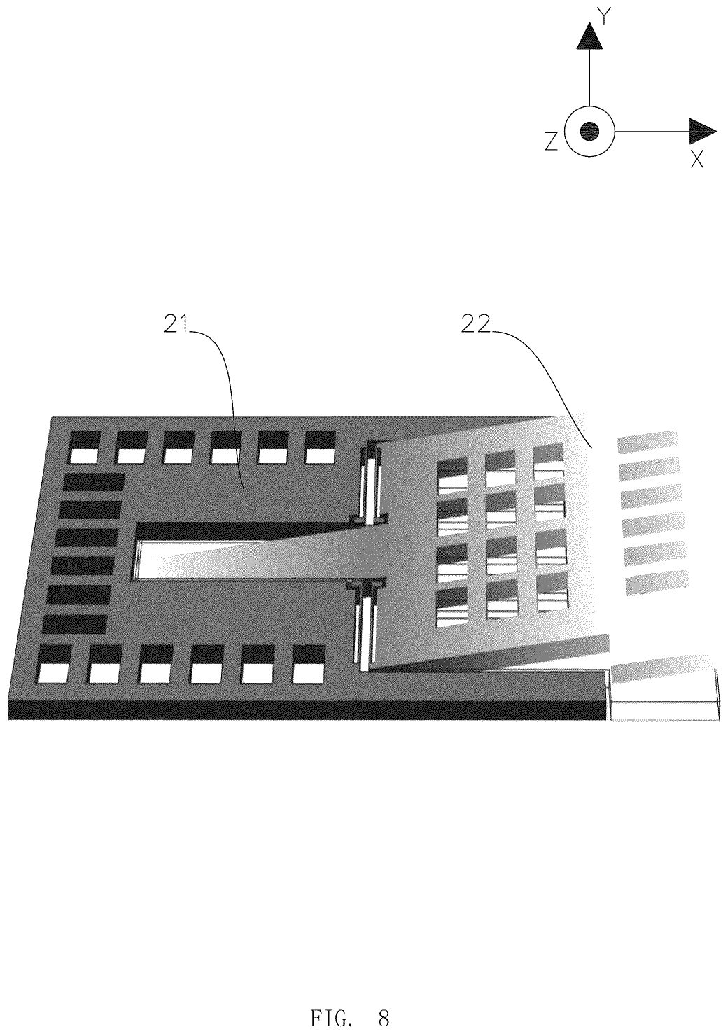

A plane where the base is located is a base plane. The anchor points 1 are fixed on the base plane. FIG. 7 and FIG. 8 show Z-axis acceleration detection modalities. Under the action of an acceleration in a Z-axis direction, the first mass block 212 of the first seesaw structure 21 rotates and tilts anticlockwise around a first rotation axis 4 (i.e. an axial line formed by the first elastic member 211 and the first anchor point 11), and the second mass block 222 of the second seesaw structure 22 rotates and tilts clockwise around a second rotation axis 5 (i.e. an axial line formed by the first elastic member 211 and the first anchor point 11); and the first rotation axis 4 and the second rotation axis 5 are in the same direction as the Y axis. FIG. 5 and FIG. 6 show Y-axis acceleration detection modalities. Under the action of an acceleration in a Y-axis direction, the first seesaw structure 21 rotates and tilts clockwise around the Z axis, and the second seesaw structure 22 rotates and tilts anticlockwise around the Z axis. FIG. 3 and FIG. 4 show X-axis acceleration detection modalities. Under an acceleration in an X-axis direction, the first seesaw structure 21 and the second seesaw structure 22 both translate along the X axis. By means of adjusting parameters of the first elastic member 211 and the second elastic member 221, corresponding modality frequencies of the various axes between the first seesaw structure 21 and the second seesaw structure 22 are close or even consistent. The first seesaw structure 21 and the second seesaw structure 22 are independent of each other. The normal phase carrier drive signal and the reversed phase carrier drive signal with opposite phases are respectively applied to the first anchor point 11 and the second anchor point 12 of the parallel and reversed first seesaw structure 21 and second seesaw structure 22. Potentials of the first seesaw structure 21 and the second seesaw structure 22 are unified with potentials at the first anchor point 11 and the second anchor point 12, respectively, to form differential drive. By a detection method in which two parallel and reversed seesaw structures 2 are driven by two carrier differential drives, when the base tilts around rotation axes where the first elastic member 211 and the second elastic member 221 are located under stress or other external factors, caused common mode changes of the differential detection assembly 3 are canceled out, which can effectively suppress the impact of noise of an angular acceleration of rotation.

The first mass block 212 and the second mass block 222 are asymmetric structures. The first mass block 212 includes a first mass portion 2121 connected to the first elastic member 211, and a second mass portion 2122 connected to the first mass portion 2121. The first mass portion 2121 and the second mass portion 2122 are asymmetric structures by taking the first rotation axis 4 as an axial line. The second mass block 222 includes a third mass portion 2221 connected to the second elastic member 221, and a fourth mass portion 2222 connected to the third mass portion 2221. The third mass portion 2221 and the fourth mass portion 2222 are asymmetric structures by taking the second rotation axis 5 as an axial line. Of course, the first mass block 212 and the second mass block 222 can also be asymmetric structures by taking the first rotation axis 4 or the second rotation axis 5 as an axial line. The moment of inertia of the first mass portion 2121 around the first elastic member 211 matches the moment of inertia of the fourth mass portion 2222 around the second elastic member 221. The moment of inertia of the second mass portion 2122 around the first elastic member 211 matches the moment of inertia of the third mass portion 2221 around the second elastic member 221.

The mass distribution of the first mass block 212 on both sides of the first elastic member 211 is asymmetric. An inertial test mass block is an asymmetric portion of the mass distribution of the first mass block 212 (i.e. an asymmetric portion taking the first rotation axis 4 as the axial line). One side of the first elastic member 211 where the first mass block 212 is located is the first mass portion 2121, and the other side of the first elastic member 211 is the second mass portion 2122. The mass distribution of the second mass block 222 on both sides of the second elastic member 221 is asymmetric. An inertial test mass block is an asymmetric portion of the mass distribution of the second mass block 222 (i.e. an asymmetric portion taking the second rotation axis 5 as the axial line). One side of the second elastic member 221 where the second mass block 222 is located is the third mass portion 2221, and the other side of the second elastic member 221 is the fourth mass portion 2222.

The first seesaw structure 21 and the second seesaw structure 22 can also be nested. At this time, the second mass portion 2122 is provided with a first matching opening 2123 in the middle, and has a shape matching that of the third mass portion 2221. The first mass portion 2121 is provided with a second matching opening 2124 in the middle, and the shape of the second matching opening 2124 matches the shape of the fourth mass portion 2222. The second matching opening 2124 is communicated with the first matching opening 2123, and a cross-sectional area of the first matching opening 2123 is larger than that of the second matching opening 2124.

The differential detection assembly 3 includes a first Z-axis capacitance detection electrode 31 arranged on the base. The first Z-axis capacitance detection electrode 31 directly faces one side of the first mass block 212 close to the first elastic member 211 and one side of the second mass block 222 facing away from the second elastic member 221, so as to form a first Z-axis differential detection capacitor and a second Z-axis differential detection capacitor. A product of an area of a plate of the first Z-axis differential detection capacitor and a distance between the plate and the first elastic member 211 is equal to a product of an area of a plate of the second Z-axis differential detection capacitor and a distance between the plate and the second elastic member 221, and plate spacings of the first Z-axis differential detection capacitor and the second Z-axis differential detection capacitor are the same.

In this embodiment, the first Z-axis differential detection capacitor and the second Z-axis differential detection capacitor in this embodiment have approximately the same overlapping areas and approximately the same plate spacings. The overlapping areas may be equal or unequal. A Z-axis out-of-plane acceleration acts on the seesaw structures 2, so that the first seesaw structure 21 rotates and tilts around a rotation axis where the first elastic member 211 is located, and the second seesaw structure 22 rotates and tilts around the second elastic member 221 in an opposite direction, and a differential change occurs in a capacitor spacing between the first Z-axis differential detection capacitor and the second Z-axis differential detection capacitor. Differential mode changes of the first Z-axis differential detection capacitor and the second Z-axis differential detection capacitor caused by the tilting of the first seesaw structure 21 and the second seesaw structure 22 can be detected by means of a capacitance detection circuit connected to the first Z-axis capacitance detection electrode 31, thus calculating the Z-axis acceleration.

When the first seesaw structure 21 and the second seesaw structure 22 are affected by noise of external angular accelerations of rotations around the first elastic member 211 and the second elastic member 221 respectively, and when the first seesaw structure 21 and the second seesaw structure 22 rotate and tilt in the same direction around the rotation axes where the first elastic member 211 and the second elastic member 221 are located respectively, caused common mode changes of the differential detection of the first Z-axis differential detection capacitor and the second Z-axis differential detection capacitor are canceled out, so that the impact of the noise of the external angular accelerations of the rotations around the first elastic member 211 and the second elastic member 221 is reduced.

When the base tilts around the rotation axes where the first elastic member 211 and the second elastic member 221 are located under stress or other external factors, the caused common mode changes of the first Z-axis differential detection capacitor and the second Z-axis differential detection capacitor are canceled out, so that the impact of the noise of the external angular accelerations of the rotations around the first elastic member 211 and the second elastic member 221 is reduced.

The differential detection assembly 3 further includes a second Z-axis capacitance detection electrode 32 arranged on the base. The second Z-axis capacitance detection electrode 32 directly faces one side of the first mass block 212 facing away from the first elastic member 211 and one side of the second mass block 222 close to the second elastic member 221, so as to form a third Z-axis differential detection capacitor and a fourth Z-axis differential detection capacitor. A product of an area of a plate of the third Z-axis differential detection capacitor and a distance between the plate and the first elastic member 211 is equal to a product of an area of a plate of the fourth Z-axis differential detection capacitor and a distance between the plate and the second elastic member 221, and plate spacings of the third Z-axis differential detection capacitor and the fourth Z-axis differential detection capacitor are the same. A product of the area of the plate of the third Z-axis differential detection capacitor and the distance between the plate and the first elastic member 211 is equal to a product of the area of the plate of the first Z-axis differential detection capacitor and the distance between the plate and the first elastic member 211, and plate spacings of the third Z-axis differential detection capacitor and the first Z-axis differential detection capacitor are the same, so as to form a dual-differential Z-axis detection capacitor.

The third Z-axis differential detection capacitor and the fourth Z-axis differential detection capacitor have an overlapping area approximately equal to that of the first Z-axis differential detection capacitor and the second Z-axis differential detection capacitor, and the plate spacings of the third Z-axis differential detection capacitor and the fourth Z-axis differential detection capacitor are approximately the same as the plate spacings of the first Z-axis differential detection capacitor and the second Z-axis differential detection capacitor, thus forming a dual-differential detection capacitor. By means of the differential detection, the anti-interference capacity and acceleration detection sensitivity of the accelerometer can be further improved. It should be noted that a product of an area of a plate of the fourth Z-axis differential detection capacitor and a distance between the plate and the second elastic member 221 is equal to a product of an area of a plate of the second Z-axis differential detection capacitor and a distance between the plate and the second elastic member 221, and plate spacings of the fourth Z-axis differential detection capacitor and the second Z-axis differential detection capacitor are the same.

The first mass block 212 further includes a first side wall 2123 perpendicular to the Y axis. The second mass block 222 further includes a second side wall 2223 perpendicular to the Y axis. The differential detection assembly 3 includes a first Y-axis capacitance detection electrode 33 arranged on the base. The first Y-axis capacitance detection electrode 33 directly faces the first side wall 2123 and the second side wall 2223 to form a first Y-axis differential detection capacitor and a second Y-axis differential detection capacitor. Plate spacings of the first Y-axis differential detection capacitor and the second Y-axis differential detection capacitor are the same.

The base is provided with the first Y-axis capacitance detection electrode 33 perpendicular to the base plane, and the first Y-axis capacitance detection electrode 33 is perpendicular to the Y axis. The first Y-axis differential detection capacitor and the second Y-axis differential detection capacitor have approximately the same overlapping areas and approximately the same plate spacings. A Y-axis acceleration acts on the seesaw structures 2, so that the first seesaw structure 21 and the second seesaw structure 22 rotates and tilts in opposite directions, and a differential change occurs in a capacitor spacing between the first Y-axis differential detection capacitor and the second Y-axis differential detection capacitor. Differential mode changes of the first Z-axis differential detection capacitor and the second Z-axis differential detection capacitor caused by the tilting of the seesaws can be detected by means of a capacitance detection circuit connected to the first Y-axis capacitance detection electrode 33, thus calculating the Y-axis acceleration.

When the first seesaw structure 21 and the second seesaw structure 22 are affected by noise of external angular accelerations of rotations around the Z axis, and when the first seesaw structure 21 and the second seesaw structure 22 rotate and tilt in the same direction around the Z-axis, caused common mode changes of the differential detection capacitors are canceled out, so that the impact of the noise of the external angular accelerations of the rotations around a central rotation axis is reduced.

The first mass block 212 further includes a third side wall 2124 opposite to the first side wall 2123. The second mass block 222 further includes a fourth side wall 2224 opposite to the second side wall 2223. The differential detection assembly 3 further includes a second Y-axis capacitance detection electrode 34 arranged on the base. The second Y-axis capacitance detection electrode 34 directly faces the third side wall 2124 and the fourth side wall 2224 to form a third Y-axis differential detection capacitor and a fourth Y-axis differential detection capacitor. Plate spacings of the third Y-axis differential detection capacitor and the fourth Y-axis differential detection capacitor are the same. The third Y-axis differential detection capacitor and the first Y-axis differential detection capacitor have the same overlapping areas and the same plate spacings, and the fourth Y-axis differential detection capacitor and the second Y-axis differential detection capacitor have the same overlapping areas and the same plate spacings, so as to form a dual-differential Y-axis detection capacitor.

The third Y-axis differential detection capacitor and the fourth Y-axis differential detection capacitor have an overlapping area approximately equal to that of the first Y-axis differential detection capacitor and the second Y-axis differential detection capacitor, and the plate spacings of the third Y-axis differential detection capacitor and the fourth Y-axis differential detection capacitor are approximately the same as the plate spacings of the first Y-axis differential detection capacitor and the second Y-axis differential detection capacitor, thus forming a dual-differential detection capacitor. By means of the differential detection, the anti-interference capacity and acceleration detection sensitivity of the accelerometer can be further improved.

The first mass block 212 further includes a fifth side wall 2125 perpendicular to the X axis. The second mass block 222 further includes a sixth side wall 2225 perpendicular to the X axis. The differential detection assembly 3 includes a first X-axis capacitance detection electrode 35 arranged on the base. The first X-axis capacitance detection electrode 35 directly faces the fifth side wall 2125 and the sixth side wall 2225 to form a first X-axis differential detection capacitor and a second X-axis differential detection capacitor. Plate spacings of the first Y-axis differential detection capacitor and the second Y-axis differential detection capacitor are the same.

The base is provided with the first X-axis capacitance detection electrode 35 perpendicular to the base plane, and the first X-axis capacitance detection electrode 35 is perpendicular to the X axis. The first X-axis differential detection capacitor and the second X-axis differential detection capacitor have approximately the same overlapping areas and approximately the same plate spacings. An X-axis acceleration acts on the seesaw structures 2, so that the first seesaw structure 21 and the second seesaw structure 22 translate around the Z axis along the X axis, and a differential change occurs in a capacitor spacing between the first X-axis differential detection capacitor and the second X-axis differential detection capacitor. Differential mode changes of the first X-axis differential detection capacitor and the second X-axis differential detection capacitor caused by the tilting of the seesaws can be detected by means of a capacitance detection circuit connected to the first X-axis capacitance detection electrode 35, thus calculating the X-axis acceleration.

The first mass block 212 further includes a seventh side wall 2126 opposite to the fifth side wall 2125. The second mass block 222 further includes an eighth side wall 2226 opposite to the sixth side wall 2225. The differential detection assembly 3 further includes a second X-axis capacitance detection electrode 36 arranged on the base. The second X-axis capacitance detection electrode 36 directly faces the seventh side wall 2126 and the eighth side wall 2226 to form a third X-axis differential detection capacitor and a fourth X-axis differential detection capacitor. Plate spacings of the third X-axis differential detection capacitor and the fourth X-axis differential detection capacitor are the same. The third X-axis differential detection capacitor and the first X-axis differential detection capacitor have the same overlapping areas and the same plate spacings, and the fourth X-axis differential detection capacitor and the second X-axis differential detection capacitor have the same overlapping areas and the same plate spacings, so as to form a dual-differential X-axis detection capacitor.

The third X-axis differential detection capacitor and the fourth X-axis differential detection capacitor have an overlapping area approximately equal to that of the first X-axis differential detection capacitor and the second X-axis differential detection capacitor, and the plate spacings of the third X-axis differential detection capacitor and the fourth X-axis differential detection capacitor are approximately the same as the plate spacings of the first X-axis differential detection capacitor and the second X-axis differential detection capacitor, thus forming a dual-differential detection capacitor. By means of the differential detection, the anti-interference capacity and acceleration detection sensitivity of the accelerometer can be further improved.

It should be noted that the acceleration of each axis can be detected by connecting a single detection electrode to a capacitance detection circuit, so that differential electrode arrangement is adopted to further improve the robustness and detection sensitivity of the accelerometer.

At least two first anchor points 11 are provided, which are oppositely arranged on the base. At least two first elastic members 211 are provided. One end of each first elastic member 211 is connected with the first mass block 212, and the other end is connected with the corresponding first anchor point 11. At least two second anchor points 12 are provided, which are oppositely arranged on the base. At least two second elastic members 221 are provided. One end of each second elastic member 221 is connected with the second mass block 222, and the other end is connected with the corresponding second anchor point 12.

The two first anchor points 11 are oppositely arranged on both sides of the third mass portion 2221, and are respectively fixed on the base. Correspondingly, the first elastic member 211 is arranged on the corresponding first anchor point 11 and connected with the first mass block 212 to achieve motion of the first seesaw. Of course, the two second anchor points 12 are oppositely arranged on both sides of the third mass portion 2221, and are respectively fixed on the base. Furthermore, the second anchor point 12 and the first anchor point 11 on the same side are spaced apart. Correspondingly, the second elastic member 221 is arranged on the corresponding second anchor point 12 and connected with the third mass portion 2221 to achieve motion of the second seesaw. It should be noted that the number of the first anchor point 11 and the number of the second anchor point 12 can also be a single or multiple, and there is no special restriction on this here, as long as the first seesaw structure 21 can be flexibly fixed to the first anchor point 11 through the first elastic member 211, and the second seesaw structure 22 can be flexibly fixed to the second anchor point 12 through the second elastic member 221. Of course, the number of the first elastic member 211 and the number of the second elastic member 221 can also be set correspondingly. In this embodiment, the first elastic member 211 and the second elastic member 221 are preferably springs. Of course, in some other embodiments, the first elastic member 211 and the second elastic member 221 can also be other types of elastic members.

The accelerometer further includes an upper cover arranged on one side of the seesaw structures 2 facing away from the base.

A plane where the upper cover is located is an upper cover plane, and the upper cover plane and the base plane are respectively located above and below a plane where the seesaw structures 2 are located. The first Z-axis capacitance detection electrode 31, the second Z-axis capacitance detection electrode 32, the second Y-axis capacitance detection electrode 34 and/or the second X-axis capacitance detection electrode 36 can also be arranged on the upper cover plane.

The implementation modes of the present invention are described above only. It should be noted that those of ordinary skill in the art can further make improvements without departing from the concept of the present invention. These improvements shall all fall within the protection scope of the present invention.

What is claimed is:

1. An accelerometer, comprising base, anchor points arranged on the base, and seesaw structures elastically connected to the anchor points, wherein the accelerometer further comprises a differential detection assembly used for detecting accelerations of the seesaw structures; the seesaw structures comprise a first seesaw structure and a second seesaw structure which are parallel to each other and placed in reverse; the anchor points comprise a first anchor point elastically connected to the first seesaw structure, and a second anchor point elastically connected to the second seesaw structure;
the first seesaw structure comprises a first elastic member connected to the first anchor point, and a first mass block connected to the first elastic member; the first mass block is driven by a normal phase carrier drive signal from the first anchor point;
the second seesaw structure comprises a second elastic member connected to the corresponding second anchor point, and a second mass block connected to the second elastic member; and the second mass block is driven by a reversed phase carrier drive signal from the second anchor point.

2. The accelerometer according to claim 1, wherein the first mass block and the second mass block are asymmetric structures;
the first mass block comprises a first mass portion connected to the first elastic member, and a second mass portion connected to the first mass portion;
the second mass block comprises a third mass portion connected to the second elastic member, and a fourth mass portion connected to the third mass portion;
the moment of inertia of the first mass portion around the first elastic member matches the moment of inertia of the fourth mass portion around the second elastic member; and the moment of inertia of the second mass portion around the first elastic member matches the moment of inertia of the third mass portion around the second elastic member.

3. The accelerometer according to claim 1, wherein the differential detection assembly comprises a first Z-axis capacitance detection electrode arranged on the base; the first Z-axis capacitance detection electrode directly faces one side of the first mass block close to the first elastic member and one side of the second mass block facing away from the second elastic member, so as to form a first Z-axis differential detection capacitor and a second Z-axis differential detection capacitor, wherein
a product of an area of a plate of the first Z-axis differential detection capacitor and a distance between the plate and the first elastic member is equal to a product of an area of a plate of the second Z-axis differential detection capacitor and a distance between the plate and the second elastic member, and plate spacings of the first Z-axis differential detection capacitor and the second Z-axis differential detection capacitor are the same.

4. The accelerometer according to claim 3, wherein the differential detection assembly further comprises a second Z-axis capacitance detection electrode arranged on the base; the second Z-axis capacitance detection electrode directly faces one side of the first mass block facing away from the first elastic member and one side of the second mass block close to the second elastic member, so as to form a third Z-axis differential detection capacitor and a fourth Z-axis differential detection capacitor, wherein
a product of an area of a plate of the third Z-axis differential detection capacitor and a distance between the plate and the first elastic member is equal to a product of an area of a plate of the fourth Z-axis differential detection capacitor and a distance between the plate and the second elastic member, and plate spacings of the third Z-axis differential detection capacitor and the fourth Z-axis differential detection capacitor are the same;
a product of the area of the plate of the third Z-axis differential detection capacitor and the distance between the plate and the first elastic member is equal to a product of the area of the plate of the first Z-axis differential detection capacitor and the distance between the plate and the first elastic member, and plate spacings of the third Z-axis differential detection capacitor and the first Z-axis differential detection capacitor are the same, so as to form a dual-differential Z-axis detection capacitor.

5. The accelerometer according to claim 2, wherein the first mass block further comprises a first side wall perpendicular to the Y axis; the second mass block further comprises a second side wall perpendicular to the Y axis; the differential detection assembly comprises a first Y-axis capacitance detection electrode arranged on the base; the first Y-axis capacitance detection electrode directly faces the first side wall and the second side wall to form a first Y-axis differential detection capacitor and a second Y-axis differential detection capacitor, wherein
plate spacings of the first Y-axis differential detection capacitor and the second Y-axis differential detection capacitor are the same.

6. The accelerometer according to claim 5, wherein the first mass block further comprises a third side wall opposite to the first side wall; the second mass block further comprises a fourth side wall opposite to the second side wall; the differential detection assembly further comprises a second Y-axis capacitance detection electrode arranged on the base; the second Y-axis capacitance detection electrode directly faces the third side wall and the fourth side wall to form a third Y-axis differential detection capacitor and a fourth Y-axis differential detection capacitor, wherein
plate spacings of the third Y-axis differential detection capacitor and the fourth Y-axis differential detection capacitor are the same; the third Y-axis differential detection capacitor and the first Y-axis differential detection capacitor have the same overlapping areas and the same plate spacings, and the fourth Y-axis differential detection capacitor and the second Y-axis differential detection capacitor have the same overlapping areas and the same plate spacings, so as to form a dual-differential Y-axis detection capacitor.

7. The accelerometer according to claim 2, wherein the first mass block further comprises a fifth side wall perpendicular to the X axis; the second mass block further comprises a sixth side wall perpendicular to the X axis; the differential detection assembly comprises a first X-axis capacitance detection electrode arranged on the base; the first X-axis capacitance detection electrode directly faces the fifth side wall and the sixth side wall to form a first X-axis differential detection capacitor and a second X-axis differential detection capacitor, wherein
plate spacings of the first X-axis differential detection capacitor and the second X-axis differential detection capacitor are the same.

8. The accelerometer according to claim 7, wherein the first mass block further comprises a seventh side wall opposite to the fifth side wall; the second mass block further comprises an eighth side wall opposite to the sixth side wall; the differential detection assembly further comprises a second X-axis capacitance detection electrode arranged on the base; the second X-axis capacitance detection electrode directly faces the seventh side wall and the eighth side wall to form a third X-axis differential detection capacitor and a fourth X-axis differential detection capacitor, wherein
plate spacings of the third X-axis differential detection capacitor and the fourth X-axis differential detection capacitor are the same; the third X-axis differential detection capacitor and the first X-axis differential detection capacitor have the same overlapping areas and the same plate spacings, and the fourth X-axis differential detection capacitor and the second X-axis differential detection capacitor have the same overlapping areas and the same plate spacings, so as to form a dual-differential X-axis detection capacitor.

9. The accelerometer according to claim 1, wherein at least two first anchor points are provided, which are oppositely arranged on the base; at least two first elastic members are provided; one end of each first elastic member is connected with the first mass block, and the other end is connected with the corresponding first anchor point;
at least two second anchor points are provided, which are oppositely arranged on the base; at least two second elastic members are provided; and one end of each second elastic member is connected with the second mass block, and the other end is connected with the corresponding second anchor point.

10. The accelerometer according to claim 2, wherein at least two first anchor points are provided, which are oppositely arranged on the base; at least two first elastic members are provided; one end of each first elastic member is connected with the first mass block, and the other end is connected with the corresponding first anchor point;
at least two second anchor points are provided, which are oppositely arranged on the base; at least two second elastic members are provided; and one end of each second elastic member is connected with the second mass block, and the other end is connected with the corresponding second anchor point.

11. The accelerometer according to claim 3, wherein at least two first anchor points are provided, which are oppositely arranged on the base; at least two first elastic members are provided; one end of each first elastic member is connected with the first mass block, and the other end is connected with the corresponding first anchor point;
at least two second anchor points are provided, which are oppositely arranged on the base; at least two second elastic members are provided; and one end of each second elastic member is connected with the second mass block, and the other end is connected with the corresponding second anchor point.

12. The accelerometer according to claim 1, further comprising an upper cover arranged on one side of the seesaw structure facing away from the base.

13. The accelerometer according to claim 1, wherein the first seesaw structure and the second seesaw structure are nested.
